(19) United States
(12) Patent Application Publication
(10) Pub. No.: US 2024/0395760 A1
(43) Pub. Date: Nov. 28, 2024

(54) SEMICONDUCTOR PACKAGE INCLUDING DAM STRUCTURE AND METHOD OF FABRICATING THE SAME

(71) Applicant: Samsung Electronics Co., Ltd., Suwon-si, Gyeonggi-do (KR)

(72) Inventor: Daeyoung Jung, Suwon-si, Gyeonggi-do (KR)

(21) Appl. No.: 18/509,930

(22) Filed: Nov. 15, 2023

(30) Foreign Application Priority Data
May 26, 2023 (KR) 10-2023-0068599

(51) Int. Cl. H01L 23/00; H01L 23/31; H01L 25/065; H10B 80/00

(52) U.S. Cl. CPC H01L 24/32; H01L 23/18; H01L 23/3128; H01L 24/26; H01L 24/73; H01L 24/83; H01L 24/85; H01L 25/18; H10B 80/00; H01L 24/16; H01L 24/48; H01L 2224/16227; H01L 2224/26175; H01L 2224/32145; H01L 2224/32225; H01L 2224/48227; H01L 2224/73204; H01L 2224/73253; H01L 2224/73265; H01L 2224/83007; H01L 2224/85013; H01L 2924/1431; H01L 2924/1436

(57) ABSTRACT

Disclosed is a semiconductor package comprising a substrate that includes bonding pads on an upper edge of the substrate, a first semiconductor chip on the substrate, a second semiconductor chip on the first semiconductor chip, a plurality of bonding wires configured to connect the second semiconductor chip to the bonding pads, a plurality of dam structures on the substrate and between the first semiconductor chip and the bonding pads, and a molding member on the plurality of dam structures, the substrate, the first semiconductor chip, and the second semiconductor chip. The plurality of dam structures includes a first dam structure having a closed loop shape that extends around the first semiconductor chip, and a second dam structure between the first dam structure and the bonding pads.

### CROSS-REFERENCE TO RELATED APPLICATION

This U.S. nonprovisional application claims priority under 35 U.S.C § 119 to Korean Patent Application No. 10-2023-0068599 filed on May 26, 2023, in the Korean Intellectual Property Office, the disclosure of which is hereby incorporated by reference in its entirety.

### BACKGROUND

The present inventive concepts relate to a semiconductor package and a method of fabricating the same, and more particularly, to a semiconductor package including a dam structure and a method of fabricating the same.

A semiconductor package is provided to implement an integrated circuit chip to qualify for use in electronic products. A semiconductor package is typically configured such that a semiconductor chip is mounted on a printed circuit board (PCB) and bonding wires or bumps are used to electrically connect the semiconductor chip to the printed circuit board. With the development of electronic industry, many studies have been conducted to improve reliability and durability of semiconductor packages.

### SUMMARY

Some embodiments of the present inventive concepts provide a semiconductor package capable of reducing or preventing overflows of underfill and organic contamination of a pad region.

Some embodiments of the present inventive concepts provide a method of fabricating a semiconductor package, which method is capable of increasing quality and yield.

According to some embodiments of the present inventive concepts, a semiconductor package may comprise: a substrate that includes bonding pads on an upper edge of the substrate; a first semiconductor chip on the substrate; a second semiconductor chip on the first semiconductor chip; a plurality of bonding wires configured to connect the second semiconductor chip to the bonding pads; a plurality of dam structures on the substrate and between the first semiconductor chip and the bonding pads; and a molding member on the plurality of dam structures, the substrate, the first semiconductor chip, and the second semiconductor chip. The plurality of dam structures may include: a first dam structure having a closed loop shape that extends around the first semiconductor chip; and a second dam structure between the first dam structure and the bonding pads.

According to some embodiments of the present inventive concepts, a semiconductor package may comprise: a substrate that includes bonding pads on an upper edge of the substrate; a first semiconductor chip on the substrate; an underfill pattern between the substrate and the first semiconductor chip; a second semiconductor chip on the first semiconductor chip; a plurality of bonding wires configured to connect the second semiconductor chip to the bonding pads; a plurality of dam structures on the substrate and between the first semiconductor chip and the bonding pads; and a molding member on the plurality of dam structures, the substrate, the first semiconductor chip, and the second semiconductor chip. The plurality of dam structures may include: a first dam structure having a closed loop shape that extends around the first semiconductor chip; and a second dam structure between the first dam structure and the bonding pads. The underfill pattern may extend on a top surface and a lateral surface of the first dam structure and contacts one lateral surface of the second dam structure.

According to some embodiments of the present inventive concepts, a semiconductor package may comprise: a substrate that includes bonding pads and upper substrate pads on a top surface of the substrate and includes lower substrate pads on a bottom surface of the substrate; a plurality of external connection members bonded to the lower substrate pads; a first semiconductor chip on the substrate; a plurality of inner connection members configured to connect the first semiconductor chip to the substrate; an underfill pattern between the substrate and the first semiconductor chip; a second semiconductor chip on the first semiconductor chip; an adhesion layer between the first semiconductor chip and the second semiconductor chip; a plurality of second chip pads on an edge of the second semiconductor chip; a plurality of dam structures on the substrate and between the first semiconductor chip and the bonding pads; a plurality of bonding wires configured to connect the second chip pads to the bonding pads; and a molding member on the plurality of dam structures, the substrate, the first semiconductor chip, and the second semiconductor chip. The plurality of dam structures may include: a first dam structure having a closed loop shape that extends around the first semiconductor chip; and a second dam structure between the first dam structure and the bonding pads. An interval between the first dam structure and the second dam structure may be in a range of about 100 μm to about 150 μm.

### BRIEF DESCRIPTION OF DRAWINGS

FIG. 1 is a simplified plan view showing a semiconductor package according to some embodiments of the present inventive concepts.

FIG. 2A is a simplified cross-sectional view taken along line I-I′ of FIG. 1, showing a semiconductor package according to some embodiments of the present inventive concepts.

FIG. 2B is a simplified cross-sectional view taken along line II-II′ of FIG. 1, showing a semiconductor package according to some embodiments of the present inventive concepts.

FIG. 2C is a simplified cross-sectional view taken along line III-III′ of FIG. 1, showing a semiconductor package according to some embodiments of the present inventive concepts.

FIG. 3A is an enlarged view showing section A of FIG. 1.

FIG. 3B is an enlarged view showing section A of FIG. 1.

FIG. 4A is a simplified cross-sectional view taken along line I-I′ of FIG. 1, showing a semiconductor package according to some embodiments of the present inventive concepts.

FIG. 4B is a simplified cross-sectional view taken along line II-II′ of FIG. 1, showing a semiconductor package according to some embodiments of the present inventive concepts.

FIG. 4C is a simplified cross-sectional view taken along line III-III′ of FIG. 1, showing a semiconductor package according to some embodiments of the present inventive concepts.

FIGS. 5A to 5I are cross-sectional views showing a method of fabricating a semiconductor package depicted in FIG. 2A.

### DETAILED DESCRIPTION OF EMBODIMENTS

Some embodiments of the present inventive concepts will now be described in detail with reference to the accompanying drawings to aid in clearly explaining the present inventive concepts.

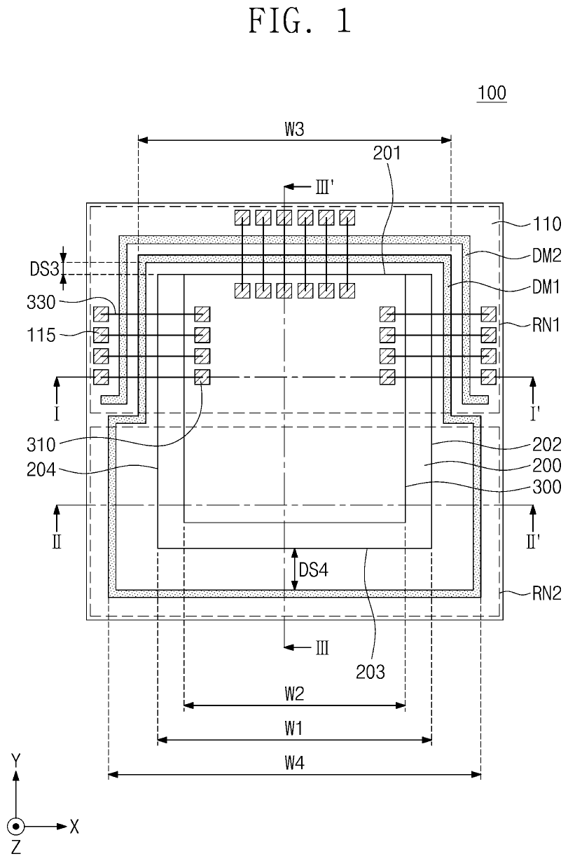

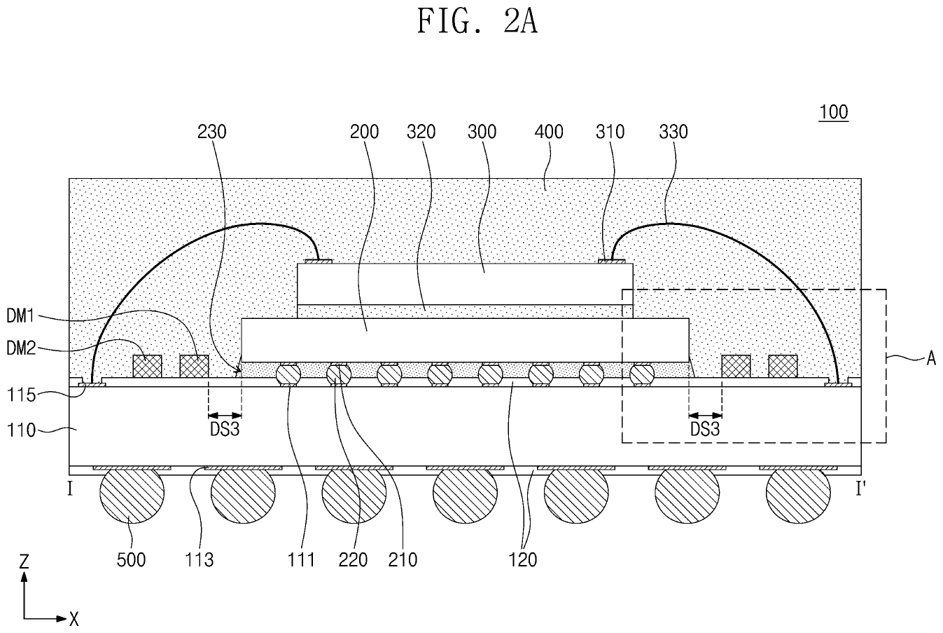

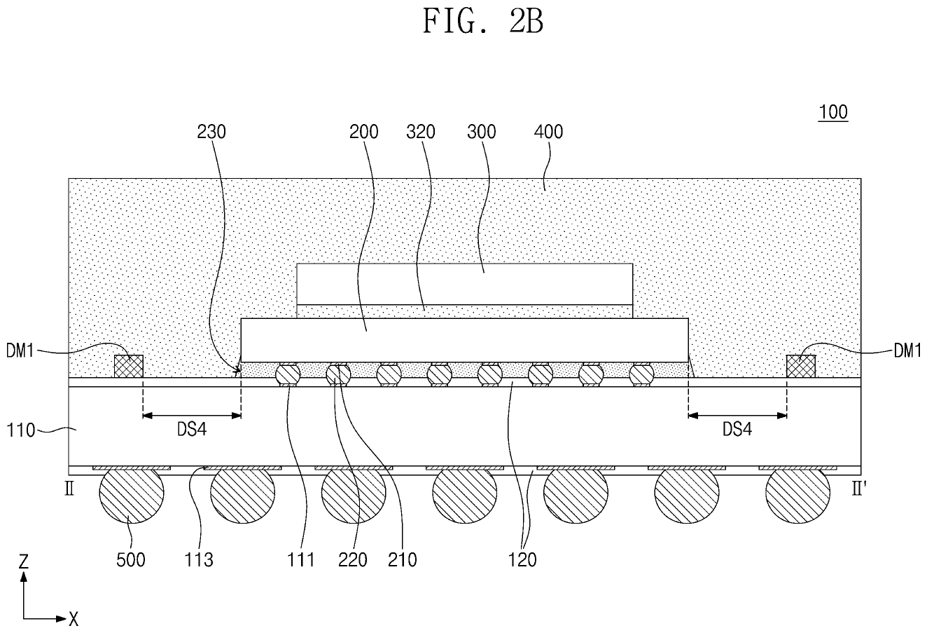

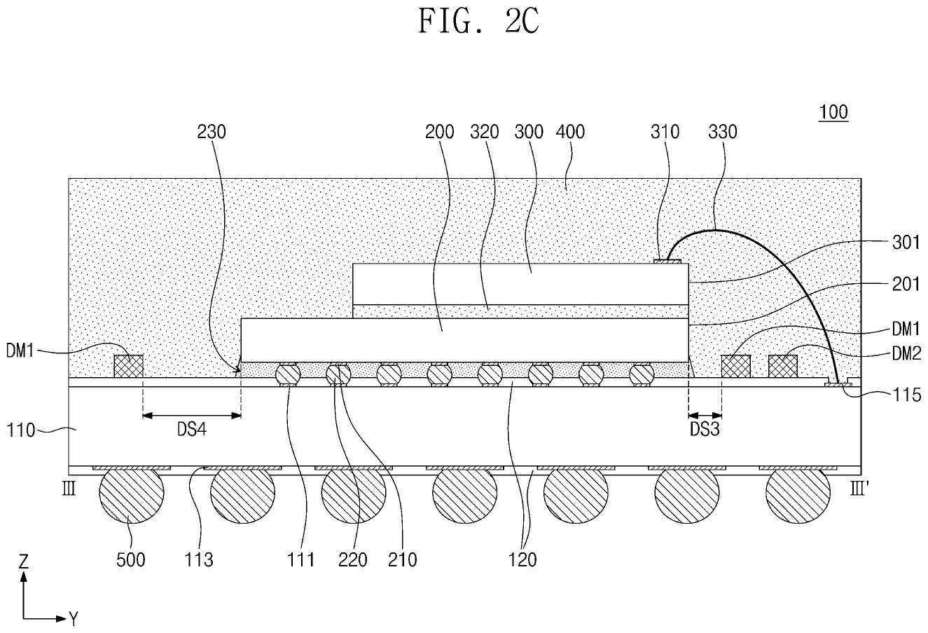

FIG. 1 is a simplified plan view showing a semiconductor package according to some embodiments of the present inventive concepts. FIGS. 2A, 2B, and 2C are simplified cross-sectional views respectively taken along lines I-I′, II-II′, and III-III′ of FIG. 1, showing a semiconductor package according to some embodiments of the present inventive concepts.

Referring to FIGS. 1 and 2A to 2C, a semiconductor package 100 according to the present embodiment may include a substrate 110, a first semiconductor chip 200, a plurality of dam structures DM1 and DM2, an underfill pattern 230, a second semiconductor chip 300, a molding member 400, and external connection members 500.

The substrate 110 may be a printed circuit board (PCB). The present inventive concepts, however, are not limited thereto, and the substrate 110 may be a silicon interposer substrate or a redistribution substrate. The substrate 110 may be called a substrate body. The substrate 110 may include a thermosetting resin such as an epoxy resin, a thermoplastic resin such as polyimide, a photo-curable resin, or a resin (e.g., prepreg) impregnated with a stiffener such as glass fiber and/or inorganic fillers. The substrate 110 may include upper substrate pads 111 on a top surface thereof and lower substrate pads 113 on a bottom surface thereof. Although not shown, a plurality of vias may be in the substrate 110. The upper substrate pads 111 may be electrically connected through the vias to corresponding lower substrate pads 113. In addition, the substrate 110 may include bonding pads 115 on the top surface thereof. The bonding pads 115 may be electrically connected through the vias to corresponding lower substrate pads 113.

A dielectric layer 120 may be on each of the top and bottom surfaces of the substrate 110. The dielectric layer 120 may not be provided on at least a portion of top surfaces of any of the upper substrate pads 111 and the bonding pads 115 so as to connect the upper substrate pads 111 and the bonding pads 115 to the first semiconductor chip 200 and the second semiconductor chip 300. In addition, the dielectric layer 120 may not be provided on at least a portion of top surfaces of any of the lower substrate pads 113 so as to connect the lower substrate pads 113 to the external connection members 500. The dielectric layer 120 may include at least one material selected from silicon nitride, polyimide, and photo solder resist (PSR).

The substrate 110 may include a first region RN1 on which the bonding pads 115 are positioned and a second region RN2 on which the bonding pads 115 are positioned. For example, as shown in the plan view of FIG. 1, the bonding pads 115 may be on opposite edges in a first direction X of the substrate 110 and one edge in a second direction Y of the substrate 110. The present inventive concepts, however, are not limited thereto. It is illustrated that the bonding pads 115 have their rectangular shapes, but in some embodiments, have their circular or oval shapes.

The first semiconductor chip 200 may be on the substrate 110. The first semiconductor chip 200 may have a rectangular shape. The first semiconductor chip 200 may be flip-chip bonded through inner connection members 220 to the substrate 110. The first semiconductor chip 200 may include first chip pads 210 on a bottom surface thereof. The inner connection members 220 may connect the first chip pads 210 to corresponding upper substrate pads 111. For example, the inner connection members 220 may include solder bumps or solder balls. The inner connection members 220 may include, for example, at least one material selected from copper, aluminum, nickel, lead, and tin.

The second semiconductor chip 300 may be on the first semiconductor chip 200. The second semiconductor chip 300 may have a rectangular shape. An adhesion layer 320 may be interposed between the first semiconductor chip 200 and the second semiconductor chip 300, and thus the first semiconductor chip 200 may be attached to the second semiconductor chip 300. The second semiconductor chip 300 may include second chip pads 310 on a top surface thereof. The second semiconductor chip 300 may be wire-bonded to the substrate 110. For example, bonding wires 330 may connect the second chip pads 310 to corresponding bonding pads 115 of the substrate 110.

The first semiconductor chip 200 may have a first width W1 in the first direction X, and the second semiconductor chip 300 may have a second width W2 in the first direction X. The first width W1 may be greater than the second width W2. The present inventive concepts, however, are not limited thereto, and the first width W1 of the first semiconductor chip 200 may be the same as the second width W2 of the second semiconductor chip 300. Referring to FIG. 2C, one sidewall 301 of the second semiconductor chip 300 may be vertically aligned with one sidewall 201 of the first semiconductor chip 200.

The first semiconductor chip 200 may include a microprocessor, a microcontroller, an application processor (AP) chip, a central processing unit (CPU), a graphic processing unit (GPU), a Modem chip, an application specific IC (ASIC), a field programmable gate array (FPGA), or any other logic chip. The second semiconductor chip 300 may include a volatile memory chip such as DRAM and SRAM, or a nonvolatile memory chip such as PRAM, MRAM, RRAM, and Flash memory. For example, the first semiconductor chip 200 may include a Modem chip, and the second semiconductor chip 300 may include a DRAM chip. The present inventive concepts, however, are not limited thereto.

FIGS. 2A to 2C depict an embodiment in which two chips 200 and 300 are stacked on the substrate 110. The present inventive concepts, however, are not limited thereto, and, for example, three or more chips may be stacked on the substrate 110.

The plurality of dam structures DM1 and DM2 may be on the top surface of the substrate 110. The plurality of dam structures DM1 and DM2 may be configured to reduce or prevent an underfill solution from an outflow from the substrate 110 when the underfill pattern 230 is formed. The plurality of dam structures DM1 and DM2 may include a first dam structure DM1 and a second dam structure DM2 that are spaced apart from each other.

As shown in the plan view of FIG. 1, the first dam structure DM1 may be between the bonding pads 115 and the first semiconductor chip 200. The first dam structure DM1 may surround or be configured to extend around, e.g., a perimeter of the first semiconductor chip 200, and may extend across the first region RN1 and the second region RN2. Referring to FIG. 1, the first dam structure DM1 may have a first width W3 in the first direction X on the first region RN1, and may also have on the second region RN2 a second width W4 in the first direction X greater than the first width W3. The first dam structure DM1 may have a closed loop shape that encloses or extends around the first semiconductor chip 200. As shown in the plan view of FIG. 1, the second dam structure DM2 may be positioned on the first region RN1 (e.g., and does not extend to the second region RN2), and may surround a portion of the first dam structure DM1 (e.g., the second dam structure DM2 is configured to extend around a portion of a perimeter of the first dam structure DM1 in the first region RN1). The second dam structure DM2 may be between the bonding pads 115 and the first dam structure DM1.

In the present embodiment, the plurality of dam structures DM1 and DM2 are illustrated to include two dam structures, but alternatively, the plurality of dam structures DM1 and DM2 may include three or more dam structures. For example, an additional dam structure may be between the first dam structure DM1 and the second dam structure DM2.

The underfill pattern 230 may fill a space between the substrate 110 and the first semiconductor chip 200. The underfill pattern 230 may include an epoxy resin, and may protect the inner connection members 220. The underfill pattern 230 may partially be on or cover the top surface of the substrate 110, and may not cover the bonding pads 115. The underfill pattern 230 may be inside the first dam structure DM1, and may be in contact with an inner lateral surface of the first dam structure DM1. The underfill pattern 230 may be between the first dam structure DM1 and a third sidewall 203 of the first semiconductor chip 200. To form the underfill pattern 230 in a process for fabricating the semiconductor package 100, an underfill solution (or an epoxy resin solution) may be provided between the substrate 110 and the first semiconductor chip 200 in a direction from the third sidewall 203 toward a first sidewall 201. As an interval between the first semiconductor chip 200 and the first dam structure DM1 is wider on the second region RN2 than on the first region RN1 on which the bonding pads 115 are present, an overflow margin of the underfill solution may increase to effectively reduce or prevent an overflow of the underfill solution. In addition, only one first dam structure DM1 may be provided on the second region RN2 on which the bonding pads 115 are absent, and thus it may be possible to simplify processes and to reduce costs. The plurality of dam structures DM1 and DM2 may include a photo solder resist (PSR) or a silicon-based polymer.

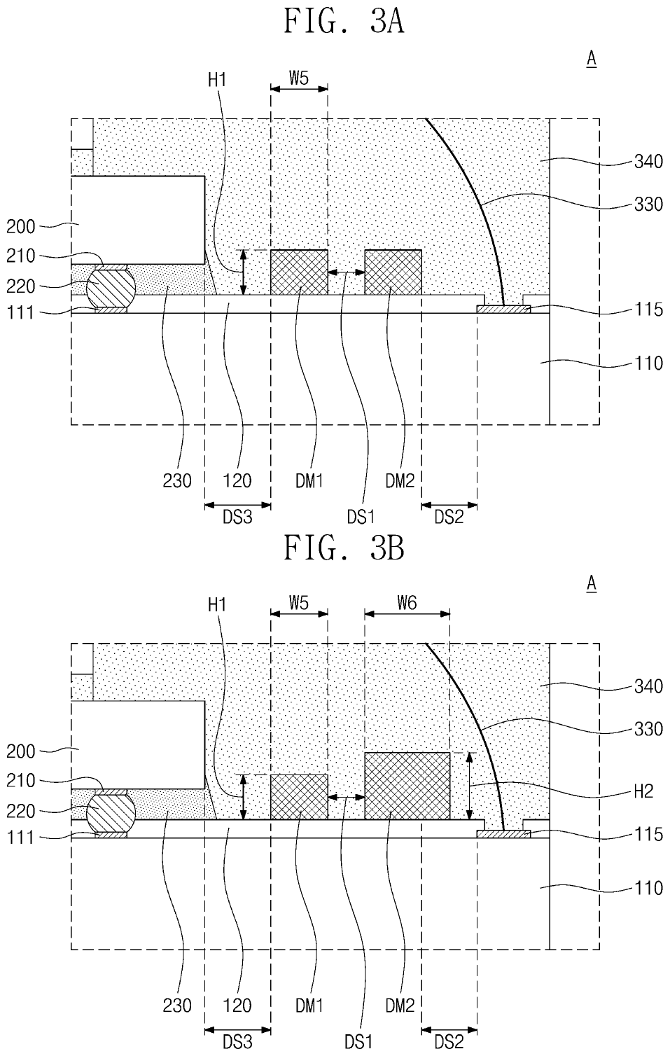

FIGS. 3A and 3B are enlarged views showing section A according to some embodiments of the present inventive concepts.

Referring to FIGS. 3A and 3B, the plurality of dam structures DM1 and DM2 may be positioned between the bonding pads 115 and the underfill pattern 230. The underfill pattern 230 may be inside the plurality of dam structures DM1 and DM2, and may be provided between the substrate 110 and the first semiconductor chip 200. An edge of the underfill pattern 230 may be positioned between the first semiconductor chip 200 and the first dam structure DM1.

The plurality of dam structures DM1 and DM2 may be formed to have a certain width and height. Referring to FIGS. 1 and 3A, the first dam structure DM1 and the second dam structure DM2 may be formed to have the same cross-sectional width and height. For example, each of the first dam structure DM1 and the second dam structure DM2 may have a cross-sectional width W5 of about 80 μm to about 120 μm and a height H1 of about 13 μm to about 23 μm. An interval DS1 between the first dam structure DM1 and the second dam structure DM2 may range from about 100 μm to about 150 μm. An interval DS2 between the second dam structure DM2 and one of the bonding pads 115 may range from about 130 μm to about 180 μm. On the first region RN1, an interval DS3 between the first dam structure DM1 and the first semiconductor chip 200 may range from about 150 μm to about 200 μm. On the second region RN2, an interval DS4 between the first dam structure DM1 and each of second, third, and fourth sidewalls 202, 203, and 204 of the first semiconductor chip 200 may range from about 525 μm to about 575 μm, and the interval DS4 may be greater than the interval DS3 between the first dam structure DM1 and the first semiconductor chip 200 on the first region RN1.

Referring to FIG. 3B, the first dam structure DM1 and the second dam structure DM2 may be formed to have different cross-sectional widths and heights. The second dam structure DM2 may be formed to have its cross-sectional width and height greater than those of the first dam structure DM1. For example, the first dam structure DM1 may have a cross-sectional width W5 of about 80 μm to about 120 μm and a height H1 of about 13 μm to about 23 μm. The second dam structure DM2 may have a cross-sectional width W6 of about 130 μm to about 170 μm and a height H2 of about 15 μm to about 25 μm. An increase in cross-sectional width and height of the second dam structure DM2 adjacent to the bonding pads 115 may reduce or prevent of an overflow of the underfill solution.

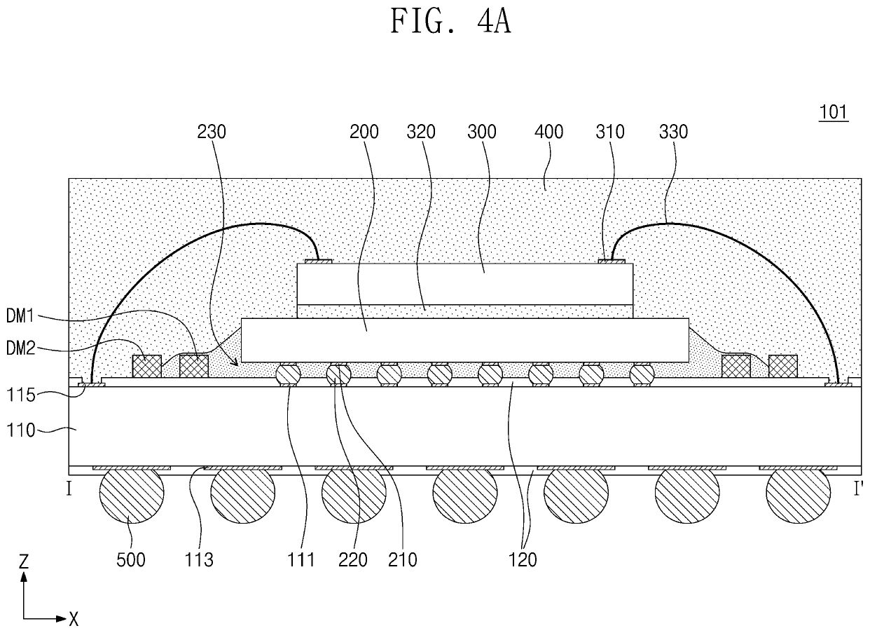

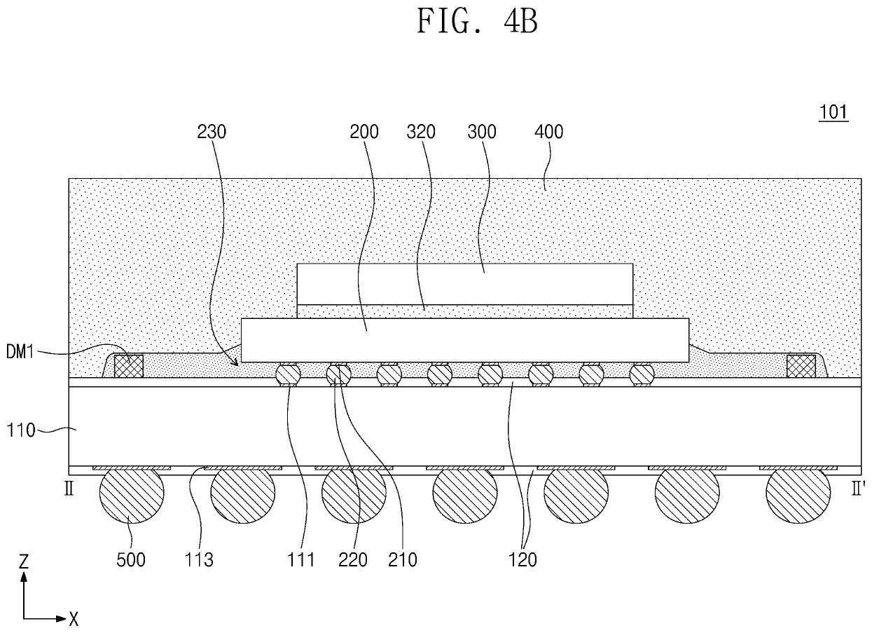

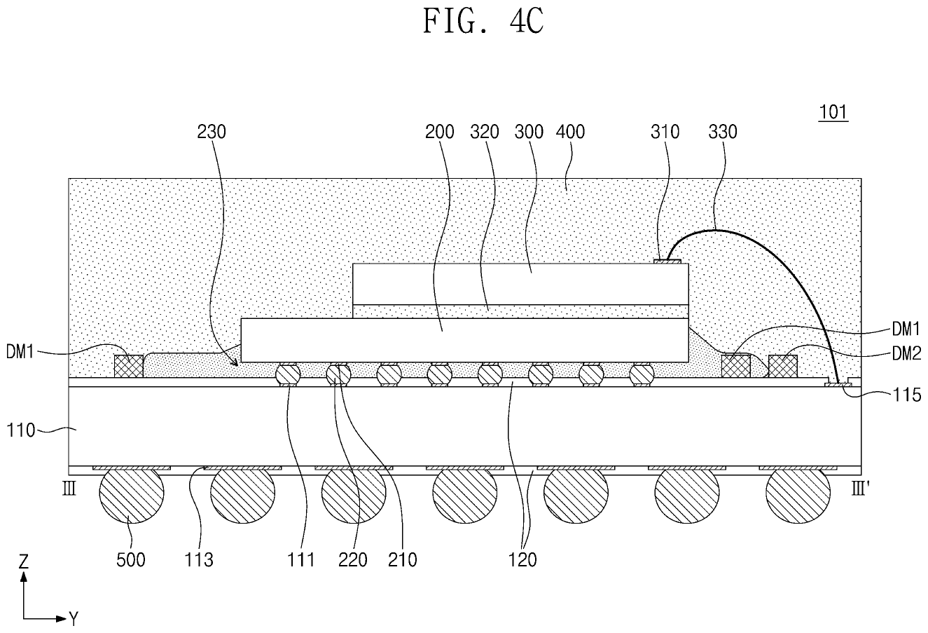

FIGS. 4A, 4B, and 4C are simplified cross-sectional views respectively taken along lines I-I′, II-II′, and III-III′ of FIG. 1, showing a semiconductor package according to some embodiments of the present inventive concepts.

Referring to FIG. 4A, a semiconductor package 101 may be configured such that, on the first region RN1, the underfill pattern 230 may extend to cover or be on a lateral surface and a top surface of the first dam structure DM1, and such that an edge of the underfill pattern 230 may be in contact with lateral surfaces of the first and second dam structures DM1 and DM2.

Referring to FIG. 4B, on the second region RN2 of the semiconductor package 101, the underfill pattern 230 may extend to cover or be on the top and lateral surfaces of the first dam structure DM1.

Referring to FIG. 4C, on the first region RN1 of the semiconductor package 101, the underfill pattern 230 may extend to cover or be on the lateral and top surfaces of the first dam structure DM1, and the edge of the underfill pattern 230 may be in contact with the lateral surfaces of the first and second dam structures DM1 and DM2. In addition, on the second region RN2, the underfill pattern 230 may extend to contact the lateral surface of the first dam structure DM1.

The molding member 400 may cover or be on the substrate 110, the first semiconductor chip 200, the second semiconductor chip 300, and the plurality of dam structures DM1 and DM2. For example, the molding member 400 may include an epoxy molding compound (EMC), but the present inventive concepts are not limited thereto.

The external connection members 500 may be on the bottom surface of the substrate 110. The external connection members 500 may be connected to corresponding lower substrate pads 113 of the substrate 110, and may be electrically connected through the lower substrate pads 113 to the upper substrate pads 111. The external connection members 500 may include, for example, solder balls. The external connection members 500 may include, for example, at least one material selected from copper, aluminum, nickel, lead, and tin.

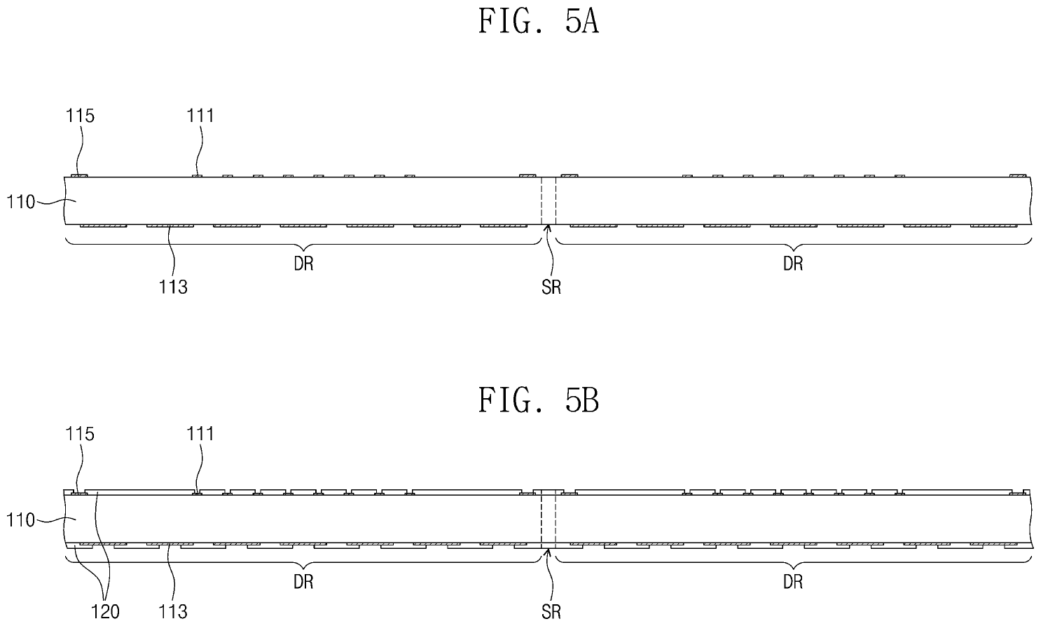

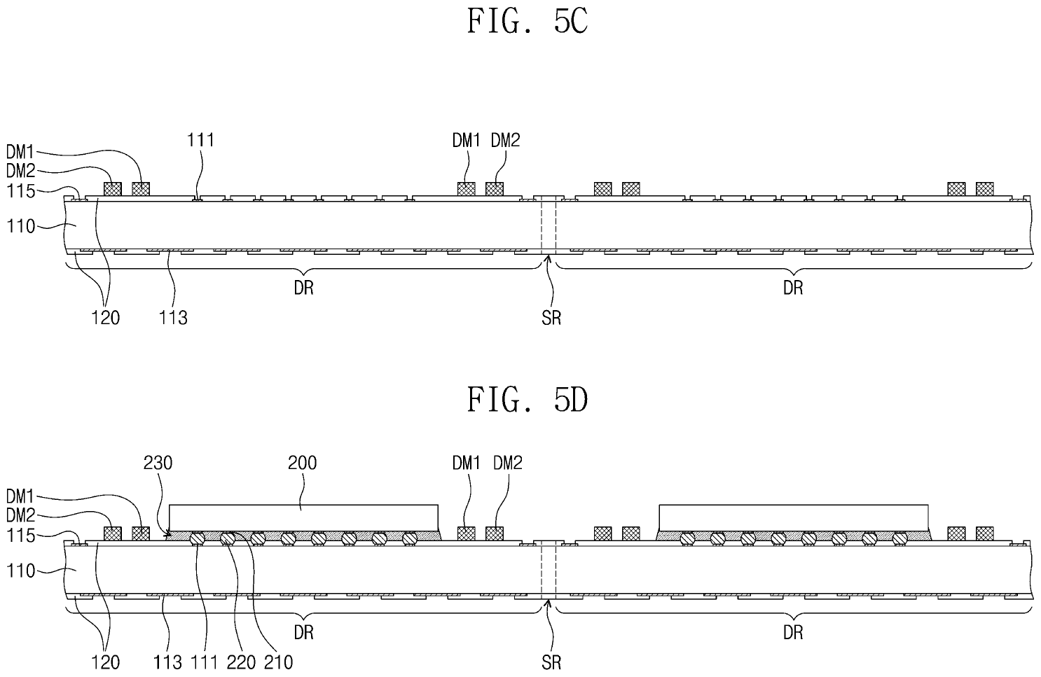

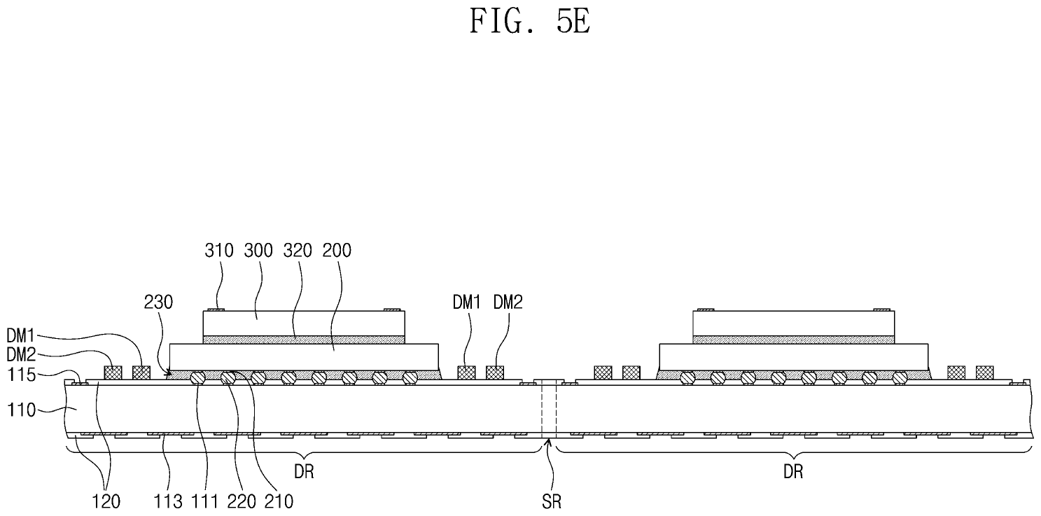

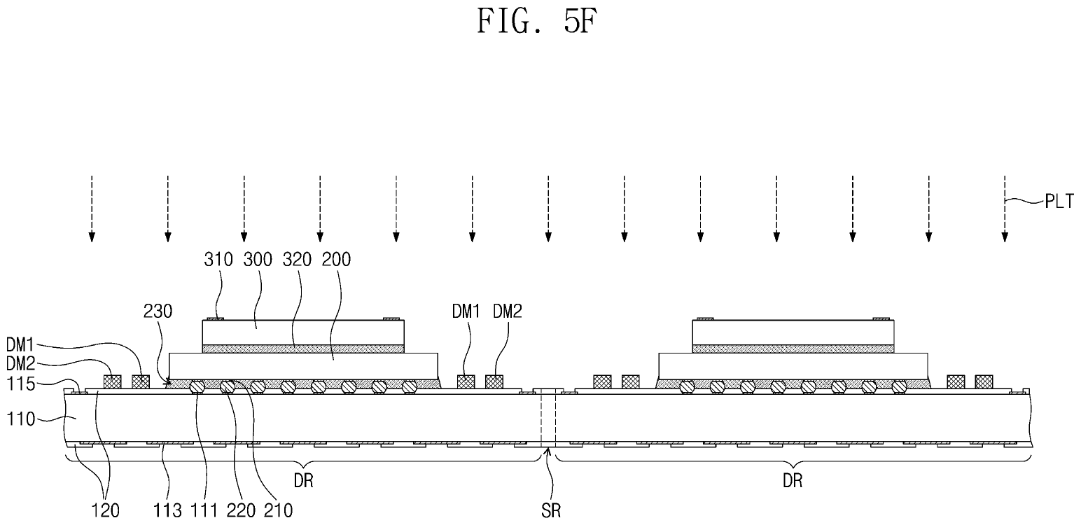

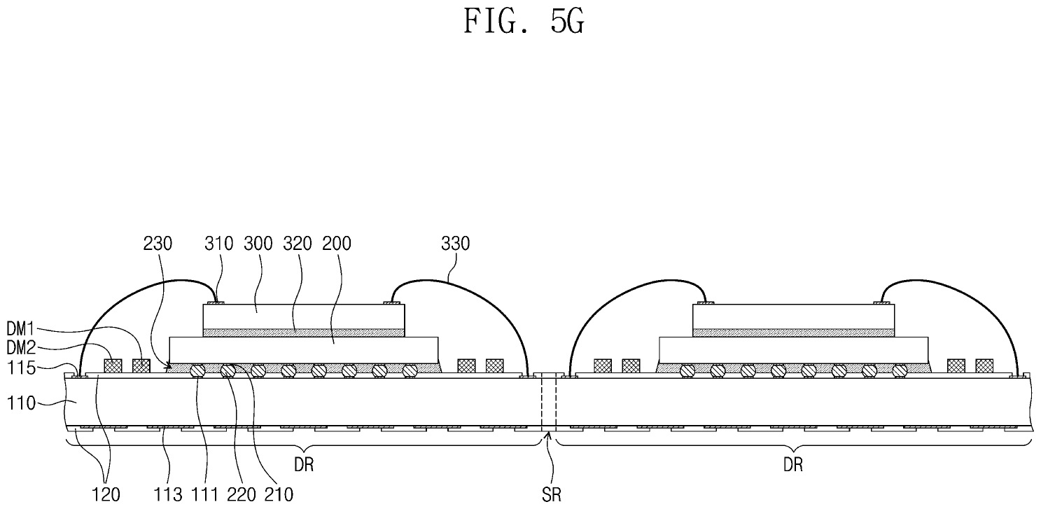

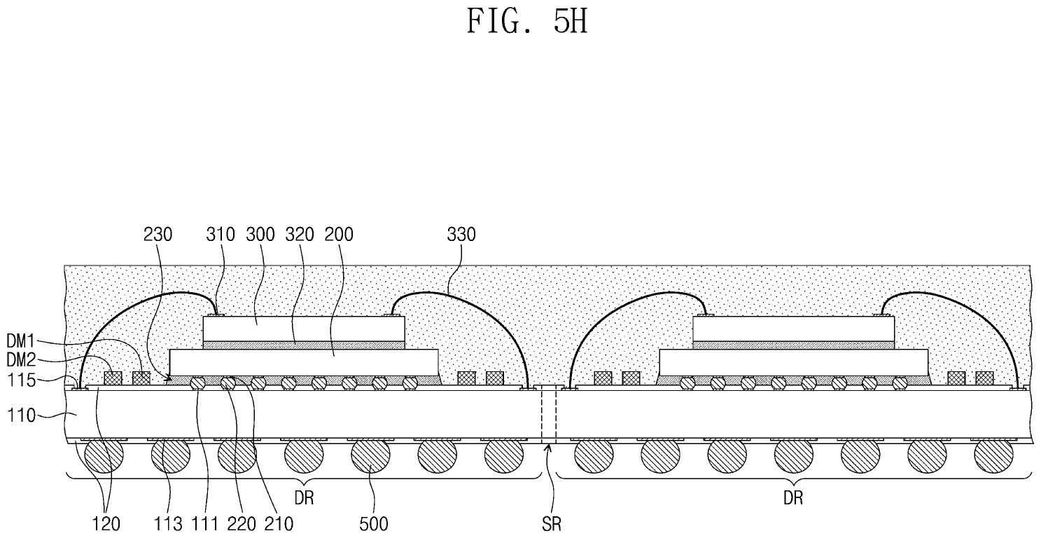

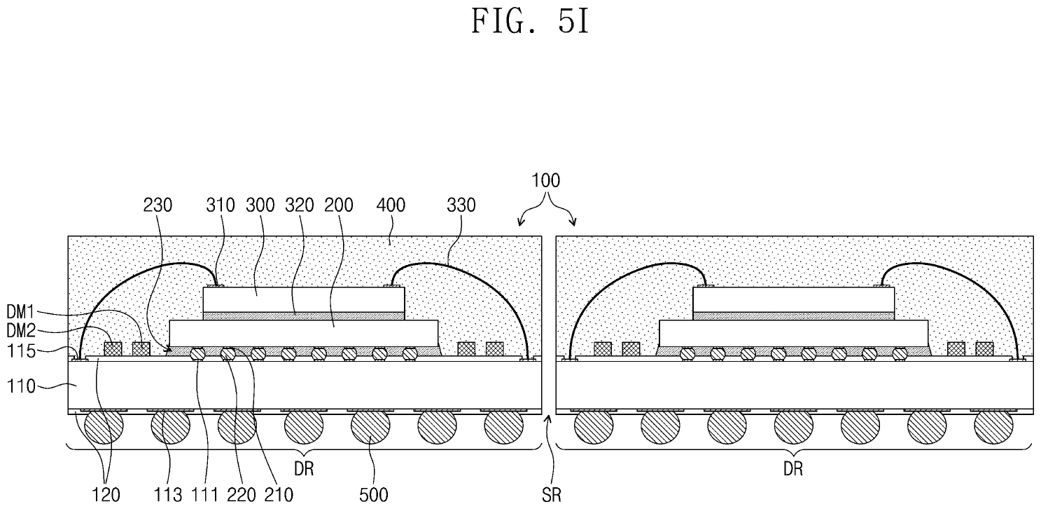

FIGS. 5A to 5I are cross-sectional views showing a method of fabricating a semiconductor package depicted in FIG. 1.

Referring to FIG. 5A, a substrate 110 may be provided. The substrate 110 may include chip regions DR and a separation region SR between the chip regions DR. The substrate 110 may include upper substrate pads 111 on a top surface thereof and lower substrate pads 113 on a bottom surface thereof. The upper substrate pads 111 may be electrically connected to corresponding lower substrate pads 113. In addition, the substrate 110 may include bonding pads 115 on the top surface thereof. The upper substrate pads 111, the lower substrate pads 113, and the bonding pads 115 may include metal, such as Al, Ti, Cr, Fe, Co, Ni, Cu, Zn, Pd, Pt, Au, and Ag.

Referring to FIG. 5B, a dielectric layer 120 may be formed on each of the top and bottom surfaces of the substrate 110. For electrical connection, the dielectric layer 120 may not be formed on any of the upper substrate pads 111, the lower substrate pads 113, and the bonding pads 115. The dielectric layer 120 may include at least one material selected from silicon nitride, polyimide, and photo solder resist (PSR).

Referring to FIG. 5C, a plurality of dam structures DM1 and DM2 may be formed on the top surface of the substrate 110. The plurality of dam structures DM1 and DM2 may be formed by, for example, a photolithography process. Alternatively, the plurality of dam structures DM1 and DM2 may be formed by coating a silicon-based polymer layer, baking the silicon-based polymer layer, and then etching the silicon-based polymer layer. The dam structures DM1 and DM2 may be formed to have the shape discussed with reference to FIGS. 1 to 3.

Referring to FIG. 5D, inner connection members 220 may be used to flip-chip bonding first semiconductor chips 200 onto each of the chip regions DR of the substrate 110. The first semiconductor chip 200 may have a rectangular shape and may include first chip pads 210 on the bottom surface thereof.

After the bonding of the first semiconductor chip 200, an underfill pattern 230 may be formed in a space between the substrate 110 and the first semiconductor chip 200. In an embodiment, the underfill pattern 230 may include an epoxy resin. The underfill pattern 230 may be formed inside the first dam structure DM1, and may not cover the bonding pads 115. The underfill pattern 230 may be formed by dispensing and curing processes. For example, a dispensing method may be employed to provide an underfill solution (or an epoxy resin solution) to a gap between the first dam structure DM1 and a third sidewall 203 of the first semiconductor chip 200, thereby filling the space between the substrate 110 and the first semiconductor chip 200. Afterwards, a curing process may be performed to form the underfill pattern 230.

Referring to FIG. 5E, a semiconductor chip 300 may be bonded onto the first semiconductor chip 200. The second semiconductor chip 300 may have a rectangular shape. The second semiconductor chip 300 may be fixed through an adhesion layer 320 onto the first semiconductor chip 200. The adhesion layer 320 may include a die attach film (DAF) or an epoxy resin. The second semiconductor chip 300 may include second chip pads 310 on a top surface thereof.

Referring to FIG. 5F, a plasma treatment process PLT may be provided. The plasma treatment process PLT may be performed before wire bonding in a strip plasma manner. As the strip plasma manner effectively removes an organic contaminant adsorbed on the bonding pads 115 after the underfill pattern 230 is cured, it may be possible to increase a bonding force of wire bonding and to decrease a failure rate.

Referring to FIG. 5G, bonding wires 330 may be formed to connect the substrate 110 to the second semiconductor chip 300. For example, the second chip pads 310 of the second semiconductor chip 300 may be electrically connected though the bonding wires 330 to the bonding pads 115 of the substrate 110.

Referring to FIG. 5H, a molding member 400 may be formed on (e.g., to cover) the substrate 110, the first semiconductor chip 200, the second semiconductor chip 300, and the plurality of dam structures DM1 and DM2. For example, the molding member 400 may include an epoxy molding compound (EMC).

After the formation of the molding member 400, external connection members 500 may be formed on the bottom surface of the substrate 110. The external connection members 500 may be electrically connected through the lower substrate pads 113 to the upper substrate pads 111. The external connection members 500 may include, for example, solder balls.

Referring to FIG. 5I, the molding member 400 and the substrate 110 may be cut along a separation region SR to form a plurality of semiconductor packages 100 separated from each other. The plurality of semiconductor packages 100 may include identical or similar properties to those of semiconductor packages discussed with reference to FIGS. 1 to 4C. In the aforementioned fabrication process, the plurality of dam structures DM1 and DM2 and the strip plasma manner may be used to provide the semiconductor package 100 with increased yield and quality.

In a semiconductor package according to the present inventive concepts, a double dam structure may reduce or prevent an underfill material from flowing toward an edge of the substrate having a bonding pad on the edge, and thus the bonding pad may be free of contamination. Therefore, contact defects between the bonding pad and a wire may be reduced or prevented to provide a semiconductor package having increased reliability.

In a method of fabricating a semiconductor package according to the present inventive concepts, as a strip plasma manner is applied to remove an organic contaminant on a contact region of the bonding pad, it may be possible to increase a bonding force of wire bonding and to decrease a failure rate. A yield may therefore increase.

Although some embodiments of inventive concepts have been discussed with reference to accompanying figures, it will be understood that various changes in form and details may be made therein without departing from the spirit and scope of inventive concepts. It will be apparent to those skilled in the art that various substitution, modifications, and changes may be thereto without departing from the scope and spirit of the present inventive concepts.

What is claimed is:

1. A semiconductor package, comprising:
a substrate including bonding pads on an upper edge of the substrate;
a first semiconductor chip on the substrate;
a second semiconductor chip on the first semiconductor chip;
a plurality of bonding wires configured to connect the second semiconductor chip to the bonding pads;
a plurality of dam structures on the substrate between the first semiconductor chip and the bonding pads; and
a molding member on the plurality of dam structures, the substrate, the first semiconductor chip, and the second semiconductor chip,
wherein the plurality of dam structures include:
a first dam structure having a closed loop shape that extends around the first semiconductor chip; and
a second dam structure between the first dam structure and the bonding pads.

2. The semiconductor package of claim 1, further comprising a plurality of inner connection members between the first semiconductor chip and the substrate, the inner connection members configured to connect the first semiconductor chip to the substrate.

3. The semiconductor package of claim 1, further comprising an adhesion layer between the first semiconductor chip and the second semiconductor chip.

4. The semiconductor package of claim 1, wherein
the first semiconductor chip includes a Modem chip or logic chip, and
the second semiconductor chip includes a memory chip.

5. The semiconductor package of claim 4, wherein
the first semiconductor chip has a first width in a first direction,
the second semiconductor chip has a second width in the first direction, the second width being less than the first width, and
one sidewall of the second semiconductor chip is vertically aligned with one sidewall of the first semiconductor chip.

6. The semiconductor package of claim 1, wherein the plurality of dam structures include a silicon-based polymer.

7. The semiconductor package of claim 1, wherein
each of the first dam structure and the second dam structure has a cross-sectional width of about 80 μm to about 120 μm, and
each of the first dam structure and the second dam structure has a height of about 13 μm to about 23 μm.

8. The semiconductor package of claim 1, wherein an interval between the first dam structure and the second dam structure is in a range of about 100 μm to about 150 μm.

9. The semiconductor package of claim 1, wherein an interval between the second dam structure and one of the bonding pads is in a range of about 130 μm to about 180 μm.

10. The semiconductor package of claim 1, wherein the substrate includes:
a first region on which the bonding pads are present; and
a second region on which the bonding pads are absent,
wherein the first dam structure extends across the first region and the second region, and
wherein the first dam structure has a first width on the first region and a second width on the second region, the second width being greater than the first width.

11. The semiconductor package of claim 10, wherein the second dam structure is on the first region and extends around a portion of the first dam structure.

12. The semiconductor package of claim 10, wherein, on the first region, an interval between the first dam structure and the first semiconductor chip is in a range of about 150 μm to about 200 μm.

13. The semiconductor package of claim 1, further comprising an underfill pattern inside the first dam structure and between the substrate and the first semiconductor chip,
wherein the underfill pattern extends on a lateral surface and a top surface of the first dam structure, and
wherein an edge of the underfill pattern is between the first dam structure and the second dam structure.

14. The semiconductor package of claim 1, further comprising an underfill pattern inside the first dam structure and between the substrate and the first semiconductor chip,
wherein an edge of the underfill pattern is between a lateral surface of the first semiconductor chip and a lateral surface of the first dam structure.

15. A semiconductor package, comprising:
a substrate that includes bonding pads on an upper edge of the substrate;
a first semiconductor chip on the substrate;
an underfill pattern between the substrate and the first semiconductor chip;
a second semiconductor chip on the first semiconductor chip;
a plurality of bonding wires configured to connect the second semiconductor chip to the bonding pads;
a plurality of dam structures on the substrate and between the first semiconductor chip and the bonding pads; and
a molding member on the plurality of dam structures, the substrate, the first semiconductor chip, and the second semiconductor chip,
wherein the plurality of dam structures include:
a first dam structure having a closed loop shape that extends around the first semiconductor chip; and
a second dam structure between the first dam structure and the bonding pads,
wherein the underfill pattern extends on a top surface and a lateral surface of the first dam structure and contacts one lateral surface of the second dam structure.

16. The semiconductor package of claim 15, wherein the substrate includes:
a first region on which the bonding pads are present; and
a second region on which the bonding pads are absent,
wherein the first dam structure extends across the first region and the second region, and
wherein the first dam structure has a first width on the first region and a second width on the second region, the second width being greater than the first width.

17. The semiconductor package of claim 16, wherein the second dam structure is on the first region and extends around a portion of the first dam structure.

18. The semiconductor package of claim 16, wherein
on the first region, the underfill pattern extends on the top surface and the lateral surface of the first dam structure and contacts a lateral surface of the second dam structure, and
on the second region, the underfill pattern extends on the top surface and the lateral surface of the first dam structure.

19. A semiconductor package, comprising:
a substrate that includes bonding pads and upper substrate pads on a top surface of the substrate and includes lower substrate pads on a bottom surface of the substrate;
a plurality of external connection members bonded to the lower substrate pads;
a first semiconductor chip on the substrate;
a plurality of inner connection members configured to connect the first semiconductor chip to the substrate;
an underfill pattern between the substrate and the first semiconductor chip;
a second semiconductor chip on the first semiconductor chip;
an adhesion layer between the first semiconductor chip and the second semiconductor chip;
a plurality of second chip pads on an edge of the second semiconductor chip;
a plurality of dam structures on the substrate and between the first semiconductor chip and the bonding pads;
a plurality of bonding wires configured to connect the second chip pads to the bonding pads; and
a molding member on the plurality of dam structures, the substrate, the first semiconductor chip, and the second semiconductor chip,
wherein the plurality of dam structures include:
a first dam structure having a closed loop shape that extends around the first semiconductor chip; and
a second dam structure between the first dam structure and the bonding pads,
wherein an interval between the first dam structure and the second dam structure is in a range of about 100 μm to about 150 μm.

20. The semiconductor package of claim 19, wherein
the first dam structure has a cross-sectional width of about 80 μm to about 120 μm and a height of about 13 μm to about 23 μm, and
the second dam structure has a cross-sectional width of about 130 μm to about 170 μm and a height of about 15 μm to about 25 μm.
